(19) United States
(12) Patent Application Publication
(10) Pub. No.: US 2014/0191810 A1
(43) Pub. Date: Jul. 10, 2014

(54) SYSTEMS AND METHODS FOR SYNTHESIZER LOCKING USING ITERATIVE NUMERICAL TECHNIQUES

(71) Applicant: QUALCOMM INCORPORATED, San Diego, CA (US)

(72) Inventor: Justin A. HWANG, Mountain View, CA (US)

(73) Assignee: QUALCOMM INCORPORATED, San Diego, CA (US)

(21) Appl. No.: 13/738,903

(22) Filed: Jan. 10, 2013

(51) Int. Cl. H03L 7/00

(52) U.S. Cl. CPC H03L 7/00
USPC 331/16

(57) ABSTRACT

This disclosure includes systems and methods for frequency synthesis using a voltage-controlled oscillator (VCO) with a programmable array of capacitors. A suitable setting for the capacitor array may be derived through a non-successive iterative numerical technique. In one aspect, the iterative numerical technique may apply Newton's method to an equation relating frequency generated by the VCO and the capacitor setting of the first programmable array of capacitors. In another aspect, a secant method may be applied to determine a capacitor array setting based on previously and currently applied capacitor settings and the corresponding measured frequencies.

### FIELD OF THE PRESENT INVENTION

This disclosure generally relates to frequency synthesizers and more specifically to techniques for rapidly tuning a voltage controlled oscillator (VCO).

### BACKGROUND OF THE INVENTION

Modern electronic circuits rely heavily on frequency synthesizers for many applications. For example, frequency synthesizers are used in wireless communication systems to convert a baseband signal to and from the higher frequency used to transmit the signal. Digital electronic circuits also utilize frequency synthesizers to generate a stable clock signal to control the operation of synchronous elements such as logic gates. In many situations, it is desirable to implement the frequency synthesizer using phase locked loop (PLL) circuitry including a VCO.

A VCO may be designed to operate at a specific frequency or a specific range of frequencies. However, a wide tuning range may degrade phase noise performance. Phase noise refers to short-term random frequency fluctuations of an oscillator signal and is a parameter used to describe the quality of the oscillator signal. Current wireless communication systems often benefit from frequency synthesizers capable of being tuned over relatively broad frequency ranges with low noise sensitivity. Accordingly, providing a wide tuning range while maintaining acceptably low phase noise is an ongoing challenge in the design of VCOs.

One technique for tuning a VCO involves switching capacitors into and out of the oscillator's inductance-capacitance (LC) resonant tank. Further, these designs may include the use of a digitally controlled, multi-bit capacitor array to provide the capacitor switching functions. The number of bits used by the capacitor array may be increased to reduce the gain of the VCO to improve phase noise performance. However, increasing the number of bits may lead to a corresponding increase in the time needed to determine the correct setting for the capacitor array to output the desired frequency.

Conventional strategies for determining the array setting involve the use of a binary search algorithm in which settings may be applied iteratively until the correct frequency is output. Generally, such techniques require a step for each bit that must be set. As the number of bits associated with the capacitor array increases, the time required for determining the corresponding programming word to configure the capacitor array to provide the desired output frequency also increases. To provide fast channel switching and achieve quick locking times, it would be desirable to employ techniques that minimize the time necessary to determine the correct setting for the capacitor array.

Accordingly, there is a need for systems and methods to rapidly determine the configuration of a digitally-switched capacitor array to tune the VCO of a frequency synthesizer. This disclosure satisfies this and other needs.

### SUMMARY OF THE INVENTION

This specification discloses methods for operating a frequency synthesizer with a voltage-controlled oscillator (VCO) having a first programmable array of capacitors that may include the steps of applying an initial setting to the first programmable array of capacitors, measuring an initial frequency generated by the VCO at the initial setting, determining a next setting for the first programmable array of capacitors using a non-successive iterative numerical technique, applying the next setting to the first programmable array of capacitors, measuring a frequency generated by the VCO at the next setting for the first programmable array of capacitors, and repeating the determination of the next setting for the first programmable array of capacitors, the application of the next setting for the first programmable array of capacitors and the measurement of the generated frequency until the current frequency is within a first desired threshold of a target frequency

In one aspect, the non-successive iterative numerical technique may be an equation relating frequency generated by the VCO and the capacitor setting of the first programmable array of capacitors. Further, the equation may be based on Newton's Method. For example, the equation may be

$${vcocap}_{n + 1} = {vcocap}_{n} + 2 \frac{{F}_{vco} ( {vcopcap}_{n} ) - {F}_{target}}{{F}_{vco} ( {vcocap}_{n} )} ( \frac{{C}_{FIXED}}{{C}_{LSB}} + {vcocap}_{n} ) ,$$

wherein C_{FIXED} is a fixed capacitance of an inductance-capacitance (LC) resonant tank of the VCO, C_{LSB} is an effective unit capacitance in the first programmable array of capacitors, vcocapₙ is a current setting of the first programmable array of capacitors, vcocapₙ₊₁ is the next setting, F_{vco}(vcocapₙ) is the current frequency generated by the VCO at the current setting and F_{target} is the target frequency.

In another aspect, the non-successive iterative numerical technique may be an equation depending upon a previously applied capacitor setting and measured frequency and a currently applied capacitor setting and measured frequency. Further, the equation may be based on a secant method. For example, the equation may be

$${vcocap}_{n + 1} = {vcocap}_{n} - [ {F}_{vco} ( {vcopcap}_{n} ) - {F}_{target} ] \frac{{vcocap}_{n} - {vcocap}_{n - 1}}{{F}_{vco} ( {vcocap}_{n} ) - {F}_{vco} ( {vcocap}_{n - 1} )} ,$$

wherein vcocapₙ₋₁ is a previous setting of the first programmable array of capacitors, vcocapₙ is a current setting of the first programmable array of capacitors, vcocapₙ₊₁ is the next setting, F_{vco}(vcocapₙ₋₁) is a frequency generated by the VCO at the previous setting, F_{vco}(vcocapₙ) is a frequency generated by the VCO at the current setting and F_{target} is the target frequency.

As desired, the methods may include applying the initial setting by estimating the initial setting based upon the target frequency.

In one embodiment, the first programmable array of capacitors may be a coarse sub-array and the VCO may have a second programmable array of capacitors configured as a fine sub-array, such that the methods may also include applying an initial setting to the second programmable array of capacitors, measuring the initial frequency generated by the VCO at the initial setting, determining a next setting for the second programmable array of capacitors using the non-successive iterative numerical technique, applying the next setting for the second programmable array of capacitors to the second programmable array of capacitors, measuring the frequency generated by the VCO at the next setting for the second programmable array of capacitors and repeating the determination of the next setting for the second programmable array of capacitors, the application of the determined setting for the second programmable array of capacitors and the measurement of the generated frequency at the next setting for the second programmable array of capacitors until the generated frequency is within a second desired threshold of the target frequency.

In another embodiment, the first programmable array of capacitors may include a coarse sub-array and a fine sub-array, such that the methods also include the steps of determining a positive slope between a frequency generated at a previous setting of the first programmable array of capacitors and a frequency generated at a current setting of the first programmable array of capacitors and adjusting the next setting of the first programmable array of capacitors by selecting a setting that generates a frequency corresponding to the frequency generated at the previous setting.

This disclosure is also directed to systems for synthesizing frequencies. In one aspect, the systems may include a frequency synthesizer with a voltage-controlled oscillator (VCO) having a first programmable array of capacitors and a programming module, wherein the programming module is configured to apply an initial setting to the first programmable array of capacitors, measure an initial frequency generated by the VCO at the initial setting, determine a next setting for the first programmable array of capacitors using a non-successive iterative numerical technique, apply the next setting to the first programmable array of capacitors, measure a current frequency generated by the VCO at the next setting and repeat the determination of the next setting for the first programmable array of capacitors, the application of the next setting for the first programmable array of capacitors and the measurement of the generated frequency until the current frequency is within a first desired threshold of a target frequency

In one aspect, the non-successive iterative numerical technique implemented by the frequency synthesizer may be an equation relating frequency generated by the VCO and the capacitor setting of the first programmable array of capacitors. Further, the equation may be based on Newton's Method. For example, the equation may be

$${vcocap}_{n + 1} = {vcocap}_{n} + 2 \frac{{F}_{vco} ( {vcopcap}_{n} ) - {F}_{target}}{{F}_{vco} ( {vcocap}_{n} )} ( \frac{{C}_{FIXED}}{{C}_{LSB}} + {vcocap}_{n} ) ,$$

wherein C_{FIXED} is a fixed capacitance of an inductance-capacitance (LC) resonant tank of the VCO, C_{LSB} is an effective unit capacitance in the first programmable array of capacitors, vcocapₙ is a current setting of the first programmable array of capacitors, vcocapₙ₊₁ is the next setting, F_{vco}(vcocapₙ) is the current frequency generated by the VCO at the current setting and F_{target} is the target frequency.

In another aspect, the non-successive iterative numerical technique implemented by the frequency synthesizer may be an equation depending upon a previously applied capacitor setting and measured frequency and a currently applied capacitor setting and measured frequency. Further, the equation may be based on a secant method. For example, the equation may be

$${vcocap}_{n + 1} = {vcocap}_{n} - [ {F}_{vco} ( {vcopcap}_{n} ) - {F}_{target} ] \frac{{vcocap}_{n} - {vcocap}_{n - 1}}{{F}_{vco} ( {vcocap}_{n} ) - {F}_{vco} ( {vcocap}_{n - 1} )} ,$$

wherein vcocapₙ₋₁ is a previous setting of the first programmable array of capacitors, vcocapₙ is a current setting of the first programmable array of capacitors, vcocapₙ₊₁ is the next setting, F_{vco}(vcocapₙ₋₁) is a frequency generated by the VCO at the previous setting, F_{vco}(vcocapₙ) is a frequency generated by the VCO at the current setting and F_{target} is the target frequency.

In some embodiments, the programming module may be configured to apply the initial setting by estimating the initial setting based upon the target frequency.

In another aspect, the frequency synthesizer may also have a second programmable array of capacitors, wherein the second programmable array of capacitors is a fine sub-array, wherein the first programmable array of capacitors is a coarse sub-array and wherein the programming module may also be configured to apply an initial setting to the second programmable array of capacitors, measure the initial frequency generated by the VCO at the initial setting, determine a next setting for the second programmable array of capacitors using the non-successive iterative numerical technique, apply the next setting for the second programmable array of capacitors to the second programmable array of capacitors, measure the frequency generated by the VCO at the next setting for the second programmable array of capacitors and repeat the determination of the next setting for the second programmable array of capacitors, the application of the determined setting for the second programmable array of capacitors and the measurement of the generated frequency at the next setting for the second programmable array of capacitors until the generated frequency is within a second desired threshold of the target frequency

In yet another aspect, the first programmable array of capacitors of the frequency synthesizer may be configured as a coarse sub-array and a fine sub-array, such that the programming module may also be configured to determine a positive slope between a frequency generated at a previous setting of the first programmable array of capacitors and a frequency generated at a current setting of the first programmable array of capacitors and adjust the next setting of the first programmable array of capacitors by selecting a setting that generates a frequency corresponding to the frequency generated at the previous setting.

The frequency synthesizers of this disclosure may be incorporated into any suitable device. Accordingly, this disclosure may also include a wireless communications device including a voltage-controlled oscillator (VCO) having a first programmable array of capacitors and a programming module, wherein the programming module is configured to apply an initial setting to the first programmable array of capacitors, measure an initial frequency generated by the VCO at the initial setting, determine a next setting for the first programmable array of capacitors using a non-successive iterative numerical technique, apply the next setting to the first programmable array of capacitors, measure a current frequency generated by the VCO at the next setting and repeat the determination of the next setting for the first programmable array of capacitors, the application of the next setting for the first programmable array of capacitors and the measurement of the generated frequency until the current frequency is within a first desired threshold of a target frequency

In one aspect, the non-successive iterative numerical technique implemented by the wireless communications device may be an equation relating frequency generated by the VCO and the capacitor setting of the first programmable array of capacitors. Further, the equation may be based on Newton's Method. For example, the equation may be

$${vcocap}_{n + 1} = {vcocap}_{n} + 2 \frac{{F}_{vco} ( {vcopcap}_{n} ) - {F}_{target}}{{F}_{vco} ( {vcocap}_{n} )} ( \frac{{C}_{FIXED}}{{C}_{LSB}} + {vcocap}_{n} ) ,$$

wherein C_{FIXED} is a fixed capacitance of an inductance-capacitance (LC) resonant tank of the VCO, C_{LSB} is an effective unit capacitance in the first programmable array of capacitors, vcocapₙ is a current setting of the first programmable array of capacitors, vcocapₙ₊₁ is the next setting, F_{vco}(vcocapₙ) is the current frequency generated by the VCO at the current setting and F_{target} is the target frequency.

In another aspect, the non-successive iterative numerical technique implemented by the wireless communications device may be an equation depending upon a previously applied capacitor setting and measured frequency and a currently applied capacitor setting and measured frequency. Further, the equation may be based on a secant method. For example, the equation may be

$${vcocap}_{n + 1} = {vcocap}_{n} - [ {F}_{vco} ( {vcopcap}_{n} ) - {F}_{target} ] \frac{{vcocap}_{n} - {vcocap}_{n - 1}}{{F}_{vco} ( {vcocap}_{n} ) - {F}_{vco} ( {vcocap}_{n - 1} )} ,$$

wherein vcocapₙ₋₁ is a previous setting of the first programmable array of capacitors, vcocapₙ is a current setting of the first programmable array of capacitors, vcocapₙ₊₁ is the next setting, F_{vco}(vcocapₙ₋₁) is a frequency generated by the VCO at the previous setting, F_{vco}(vcocapₙ) is a frequency generated by the VCO at the current setting and F_{target} is the target frequency.

In some embodiments, the programming module may be configured to apply the initial setting by estimating the initial setting based upon the target frequency.

In another aspect, the wireless communications device may also have a second programmable array of capacitors, wherein the second programmable array of capacitors is a fine sub-array, wherein the first programmable array of capacitors is a coarse sub-array and wherein the programming module may also be configured to apply an initial setting to the second programmable array of capacitors, measure the initial frequency generated by the VCO at the initial setting, determine a next setting for the second programmable array of capacitors using the non-successive iterative numerical technique, apply the next setting for the second programmable array of capacitors to the second programmable array of capacitors, measure the frequency generated by the VCO at the next setting for the second programmable array of capacitors and repeat the determination of the next setting for the second programmable array of capacitors, the application of the determined setting for the second programmable array of capacitors and the measurement of the generated frequency at the next setting for the second programmable array of capacitors until the generated frequency is within a second desired threshold of the target frequency

In yet another aspect, the first programmable array of capacitors of the wireless communications device may be configured as a coarse sub-array and a fine sub-array, such that the programming module may also be configured to determine a positive slope between a frequency generated at a previous setting of the first programmable array of capacitors and a frequency generated at a current setting of the first programmable array of capacitors and adjust the next setting of the first programmable array of capacitors by selecting a setting that generates a frequency corresponding to the frequency generated at the previous setting.

### BRIEF DESCRIPTION OF THE DRAWINGS

Further features and advantages will become apparent from the following and more particular description of the preferred embodiments of the invention, as illustrated in the accompanying drawings, and in which like referenced characters generally refer to the same parts or elements throughout the views, and in which:

FIG. 1 schematically depicts functional blocks of a VCO having a multi-bit capacitor array, according to an embodiment of the invention;

FIG. 2 depicts a flow chart representing a routine for tuning a VCO having a multi-bit capacitor array, according to an embodiment of the invention;

FIG. 3 represents simulated results of a routine for tuning a VCO having a multi-bit capacitor array, according to an embodiment of the invention;

FIG. 4 represents simulated results of a routine for tuning a VCO having a multi-bit capacitor array using directed initial settings, according to an embodiment of the invention;

FIG. 5 schematically depicts functional blocks of a multi-bit capacitor array having a coarse sub-array and a fine sub-array, according to an embodiment of the invention;

FIG. 6 represents a portion of a frequency tuning curve of a VCO, according to an embodiment of the invention;

FIG. 7 represents a routine for tuning a VCO having a multi-bit capacitor array with respect to a portion of a frequency tuning curve of a VCO, according to an embodiment of the invention; and

FIG. 8 schematically depicts functional blocks of a wireless transceiver having a VCO with a multi-bit capacitor array, according to an embodiment of the invention.

### DETAILED DESCRIPTION OF THE INVENTION

At the outset, it is to be understood that this disclosure is not limited to particularly exemplified materials, architectures, routines, methods or structures as such may, of course, vary. Thus, although a number of such options, similar or equivalent to those described herein, can be used in the practice or embodiments of this disclosure, the preferred materials and methods are described herein.

It is also to be understood that the terminology used herein is for the purpose of describing particular embodiments of this disclosure only and is not intended to be limiting.

The detailed description set forth below in connection with the appended drawings is intended as a description of exemplary embodiments of the present invention and is not intended to represent the only exemplary embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the specification. It will be apparent to those skilled in the art that the exemplary embodiments of the specification may be practiced without these specific details. In some instances, well known structures and devices are shown in block diagram form in order to avoid obscuring the novelty of the exemplary embodiments presented herein.

For purposes of convenience and clarity only, directional terms, such as top, bottom, left, right, up, down, over, above, below, beneath, rear, back, and front, may be used with respect to the accompanying drawings or chip embodiments. These and similar directional terms should not be construed to limit the scope of the invention in any manner.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

“Complementary logic,” which refers to logic circuitry involving both P-channel and N-channel transistors, is often more commonly referred to as CMOS (Complementary Metal Oxide Semiconductor) logic even though the transistors making up the logic circuitry may not have metal gates and may not have oxide gate dielectrics.

The terms second level and first level, high and low and 1 and 0, as used in the following description may be used to describe various logic states as known in the art. Particular voltage values of the second and first levels are defined arbitrarily with regard to individual circuits. Furthermore, the voltage values of the second and first levels may be defined differently for individual signals such as a clock and a digital data signal. Although specific circuitry has been set forth, it will be appreciated by those skilled in the art that not all of the disclosed circuitry is required to practice the invention. Moreover, certain well known circuits have not been described, to maintain focus on the invention. Similarly, although the description refers to logical “0” and logical “1” or low and high in certain locations, one skilled in the art appreciates that the logical values can be switched, with the remainder of the circuit adjusted accordingly, without affecting operation of the present invention.

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

Unless defined otherwise, all technical and scientific terms used herein have the same meaning as commonly understood by one having ordinary skill in the art to which the disclosure pertains.

Finally, as used in this specification and the appended claims, the singular forms “a, “an” and “the” include plural referents unless the content clearly dictates otherwise.

As described above, a frequency synthesizer exhibiting a wide tuning range and low phase noise may be implemented by using a VCO with a multi-bit capacitor array. The capacitor array may include a bank of tuning capacitors configured to be switched on or off individually. Since the resonant frequency of the VCO depends upon the inductance and capacitance of the LC resonant tank, each tuning capacitor may reduce the oscillation frequency when switched on. In one design, the tuning capacitors may have binary weighted capacitances, such that the first tuning capacitor in the bank has unit capacitance and each subsequent tuning capacitor has twice the capacitance of the preceding tuning capacitor. The unit capacitance may correspond to the least significant bit (LSB) of the programming word used to configure the capacitor array. Thus, different total tuning capacitances, in progressively larger discrete steps, may be obtained by switching on one or more of the appropriate tuning capacitors. In another design, the tuning capacitors may have substantially equivalent capacitances, with each capacitor controlled by one bit of the programming word in a “thermometer encoded” configuration. Further, suitable designs may also include an array having a combination of binary weighted and thermometer encoded capacitors. For example, thermometer encoding may be used for the most significant bit (MSB) units and binary weighting may be used for the LSB units. The techniques of this disclosure may be applied to any capacitor array design as desired.

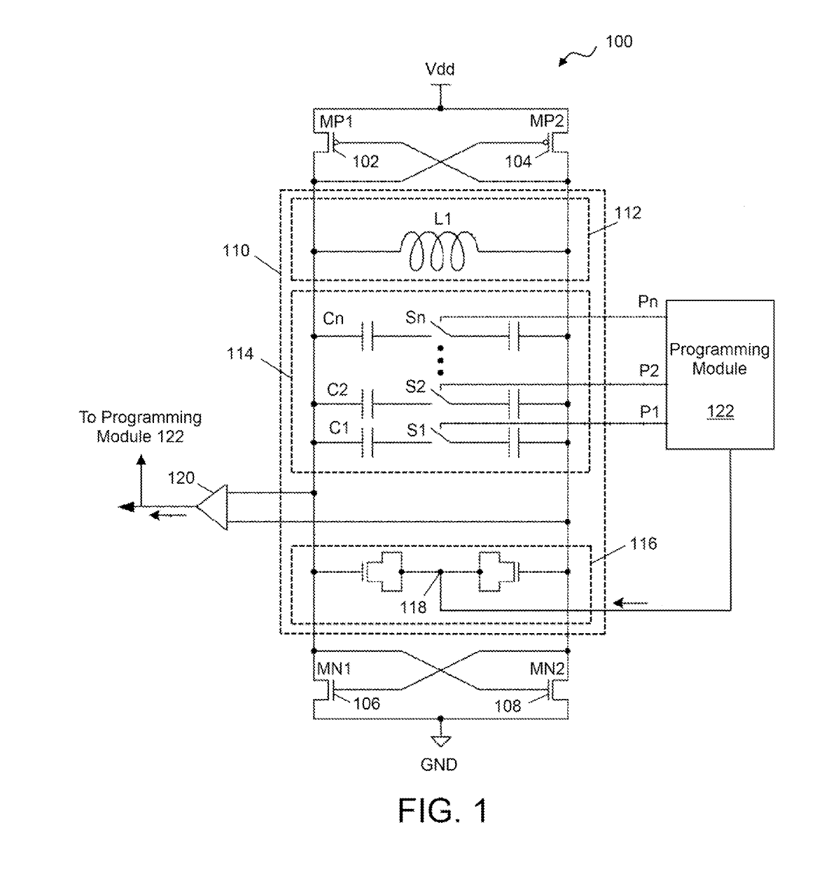

Turning now to FIG. 1, one embodiment of a frequency synthesizer suitable for use with this disclosure is shown in the form of VCO 100. Generally, VCO 100 may be implemented in a CMOS process and includes cross-coupled PMOS and NMOS transistor pairs formed by MP1 102, MP2 104, MN1 106 and MN2 108. PMOS transistor pair MP1 102 and MP2 104 is coupled to supply voltage VDD and NMOS transistor pair MN1 106 and MN2 108 is coupled to ground. VCO 100 also includes LC resonant tank 110 formed by inductor L1 112, multi-bit capacitor array 114 and varactor 116, each coupled in parallel. Accordingly, a control voltage applied to node 118 of varactor 116 induces resonance at a frequency determined by the values of inductor L1 112, multi-bit capacitor array 114 and varactor 116 to generate a frequency signal F_{vco}(vcocap) at the output of buffer 120.

In more detail, multi-bit capacitor array 114 includes a plurality of capacitor pairs C1-Cn coupled in parallel and switched in and out of LC resonant tank 110 by switches S1-Sn. Each switch is controlled by corresponding programmable control lines P1-Pn. As will be described below, control lines P1-Pn may be set by an appropriate programming word as determined by programming module 122, which receives F_{vco}(vcocap) and may also be configured to output the control voltage applied to varactor 116. By applying the appropriate programming word to control lines P1-Pn, the capacitance of multi-bit capacitor array 114 may be set to a desired value vcocap within the range to generate the corresponding output signal F_{vco}(vcocap).

The appropriate programming word may be determined by employing an iterative search according to the general equation (1):

f(vcocap)=F_{vco}(vcocap)−F_{target}=0, (1)

where F_{vco}(vcocap) is the frequency of the VCO at the vcocap setting and F_{target} is the desired frequency. In one aspect, a suitable iterative numerical technique may be applied to determine the root of the equation and, correspondingly, the appropriate programming word.

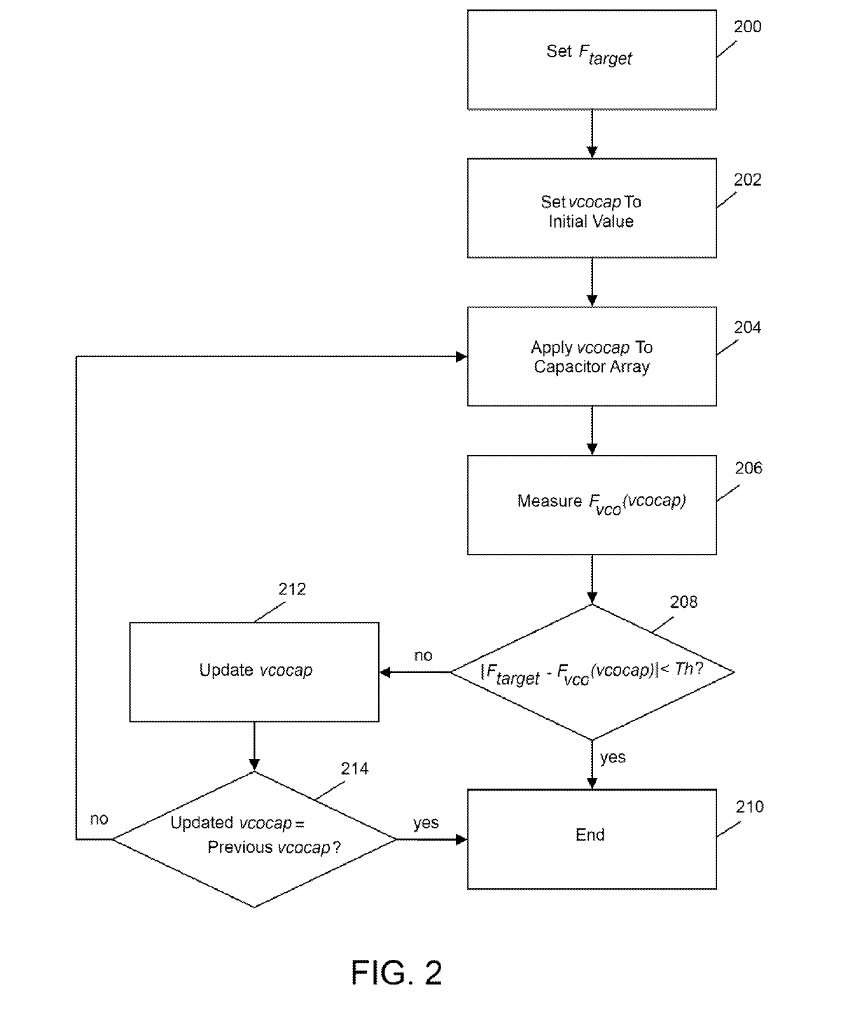

One suitable routine for implementing the techniques of this disclosure is represented by the flow chart of FIG. 2. As shown, programming module 122 may set the desired frequency F_{target} based upon the operational context of VCO 100 or by any other suitable means as represented by step 200. Next, programming module 122 may set an initial vcocap in step 202. Depending upon the embodiment, the initial value may be determined in any suitable manner. For example, the initial value may simply represent a median value within the range of vcocap settings. Alternatively, as will be described below, the initial value may represent a partitioned vcocap estimation based upon F_{target}. Other methods may be used to determine an initial vcocap as desired. The vcocap setting may be translated to an appropriate programming word and applied to multi-bit capacitor array 114 in step 204. Programming module 122 may then measure the resulting F_{vco}(vcocap) in step 206.

The routine may branch as indicated at step 208, such that if the difference between F_{vco}(vcocap) and F_{target} is within a suitable threshold value Th, programming module 122 may determine that the appropriate programming word has been determined and the routine may exit as indicated by step 210. Alternatively, if the difference between F_{vco}(vcocap) and F_{target} is not within the threshold, programming module 122 may determine an updated vcocap as indicated by step 212. As will be described below, programming module 122 may determine the updated vcocap based upon a suitable, non-successive iterative numerical technique. The updated vcocap is compared to the previous vcocap in step 214. If the vcocaps are equivalent, programming module 122 may determine that the iterative numerical technique has converged and the routine may exit as indicated by step 210. Alternatively, if the updated vcocap differs from the previous vcocap, the routine may return to step 204 to apply the updated vcocap to multi-bit capacitor array 114.

As noted above, conventional techniques for determining the setting of a programmable multi-bit capacitor array may employ a successive iterative search algorithm. Generally, a step is performed for each successive bit, from the most significant bit (MSB) to the LSB. For example, in a typical wireless communication application, a ten bit capacitor array may be employed to provide the desired tuning range. Correspondingly, a conventional successive iterative search may require up to ten steps to determine the appropriate programming word which represent a significant amount of time.

By employing the techniques of this disclosure, the number of steps needed to converge at an appropriate solution may be reduced, resulting in improved locking times and faster channel switching. The techniques of this disclosure employ non-successive iterative numerical techniques, such that more than one bit of the appropriate programming word may be determined in each step. As a result, the number of steps required to converge at a solution may be less than the number of bits in the programming word, representing a more efficient determination. Accordingly, programming module 122 may be configured to determine an updated vcocap in step 212 using a non-successive iterative numerical technique.

In one embodiment, F_{vco}(vcocap) may be modeled as a function of the inductance and capacitance of LC resonant tank 110 using the relationship 1/(LC)^{-1/2}, allowing equation (1) to be rewritten as equation (2) as follows:

$$f ( vcocap ) \approx {K ( \frac{1}{2 π} ) [ L ( {C}_{FIXED} + vcocap * {C}_{LSB} ) ]}^{- 1 / 2} - {F}_{target} , \qquad ( 2 )$$

wherein L is the inductance of LC resonant tank 110, C_{FIXED} is the fixed capacitance of LC resonant tank 110, vcocap is the n-bit capacitor setting, C_{LSB} is the effective unit capacitance in the capacitor array, and K is an arbitrary scaling constant. Newton's Method refers to a technique that may be used to determine successively better estimated solutions for the root of a function and may be represented generally by equation (3):

$${x}_{n + 1} = {x}_{n} - \frac{f ( {x}_{n} )}{{f}^{′} ( {x}_{n} )} \qquad ( 3 )$$

Accordingly, in order to apply Newton's method, the derivative of equation (2) may be represented by equation (4) as follows:

$${f}^{′} ( vcocap ) = ( - \frac{1}{2} ) {K ( \frac{1}{2 π} ) [ L ( {C}_{FIXED} + vcocap * {C}_{LSB} ) ]}^{- 3 / 2} * L * {C}_{LSB} \qquad ( 4 )$$

Further, equation (4) may be simplified by rewriting in terms of the original F_{vco}(vcocap) to remove the rational exponent, resulting in equation (5):

$${f}^{′} ( vcocap ) = ( - \frac{1}{2} ) [ {F}_{vco} ( vcocap ) ] ( \frac{1}{\frac{{C}_{FIXED}}{{C}_{LSB}} + vcocap} ) \qquad ( 5 )$$

Accordingly, by incorporating equation (2) and equation (5) in Newton's Method as represented by equation (3), a suitable non-successive iterative numerical technique for determining an updated vcocap may be expressed by equation (6) as follows:

$${vcocap}_{n + 1} = {vcocap}_{n} + 2 \frac{{F}_{vco} ( {vcopcap}_{n} ) - {F}_{target}}{{F}_{vco} ( {vcocap}_{n} )} ( \frac{{C}_{FIXED}}{{C}_{LSB}} + {vcocap}_{n} ) \qquad ( 6 )$$

By employing equation (6), programming module 122 may be configured to determine an updated vcocap in step 212 based upon one parameter, the ratio of the fixed capacitance in LC resonant tank 110 to the unit LSB capacitance of multi-bit capacitor array 114. Convergence may be achieved when F_{vco}(vcocap) is within the threshold Th of F_{target} in step 208 or when the updated vcocap is equivalent to the previous vcocap in step 214.

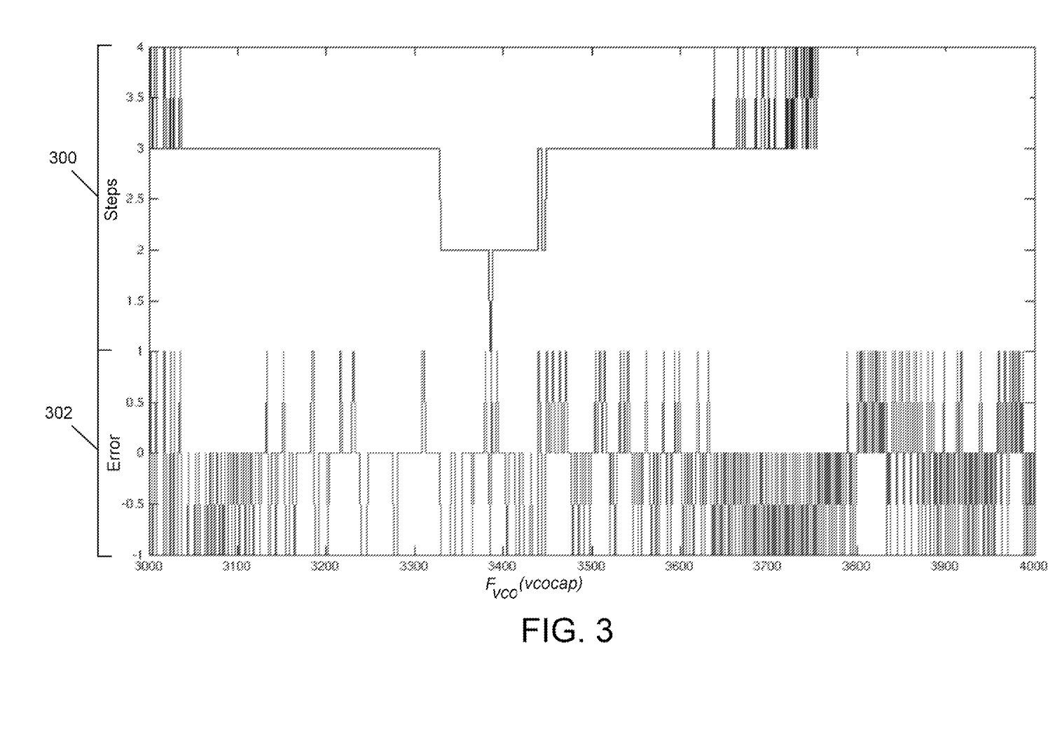

Using the above technique allows for a determination of the appropriate array setting in a number of steps approximately equal to the square root of the number of bits. For example, a simulation of the iterative algorithm of equation (6) as implemented by programming module 122 of VCO 100 having a 10-bit capacitor array is depicted in FIG. 3. As shown, the target frequency is swept from 3000 to 4000 along the x-axis, and the number of iterations 300 required for convergence, as well as the residual error 302 after convergence, are shown on the y-axis. This simulation indicates that programming module 122 may converge at an appropriate programming word in four steps or less when employing the non-successive iterative numerical technique of equation (6), with an error of +/−1 LSB. Further, the average number of steps required to achieve convergence is 3.16 steps. This represents a considerable efficiency as compared to the 10 steps that would be required for a conventional binary search.

In another embodiment, the non-successive iterative numerical technique implemented by programming module 122 to update the vcocap in step 212 may be a secant method. By using a previous vcocap and the resulting F_{vco}(vcocap) in conjunction with a currently applied vcocap and the resulting F_{vco}(vcocap), a suitable next vcocap may be determined as indicated by equation (7):

$${vcocap}_{n + 1} = {vcocap}_{n} - [ {F}_{vco} ( {vcocap}_{n} ) - {F}_{target} ] \frac{{vcocap}_{n} - {vcocap}_{n - 1}}{{F}_{vco} ( {vcocap}_{n} ) - {F}_{vco} ( {vcocap}_{n - 1} )} \qquad ( 7 )$$

Using this approach, an appropriate setting for the capacitor array may be determined in an average of n̂(1/1.618) iterations for an n-bit array. For example, simulations have determined that the capacitor setting for a 10 bit array may be determined in approximately 4.15 steps.

As referenced above, a further aspect of this disclosure relates to the initial vcocap determined by programming module 122 in step 202. Rather than employing an arbitrary initial vcocap or a vcocap that is a median of the range of vcocap settings, programming module 122 may determined a directed initial setting based on the desired target frequency or by modifying the non-successive iterative numerical technique based on known characteristics of the tuning curve.

In one example, when VCO 100 is configured for use in a wireless communications application, it may be designed to provide frequencies over a desired tuning range. In turn, the range of vcocap settings may correlate to range of frequencies. Accordingly, programming module 122 may be configured to perform a binning procedure for the range of frequencies to partition them into a plurality of bins. Further, an initial vcocap may be set for each bin. By determining which bin the desired F_{target} belongs, programming module 122 may select the corresponding initial vcocap in order to further optimize the determination of the appropriate programming word.

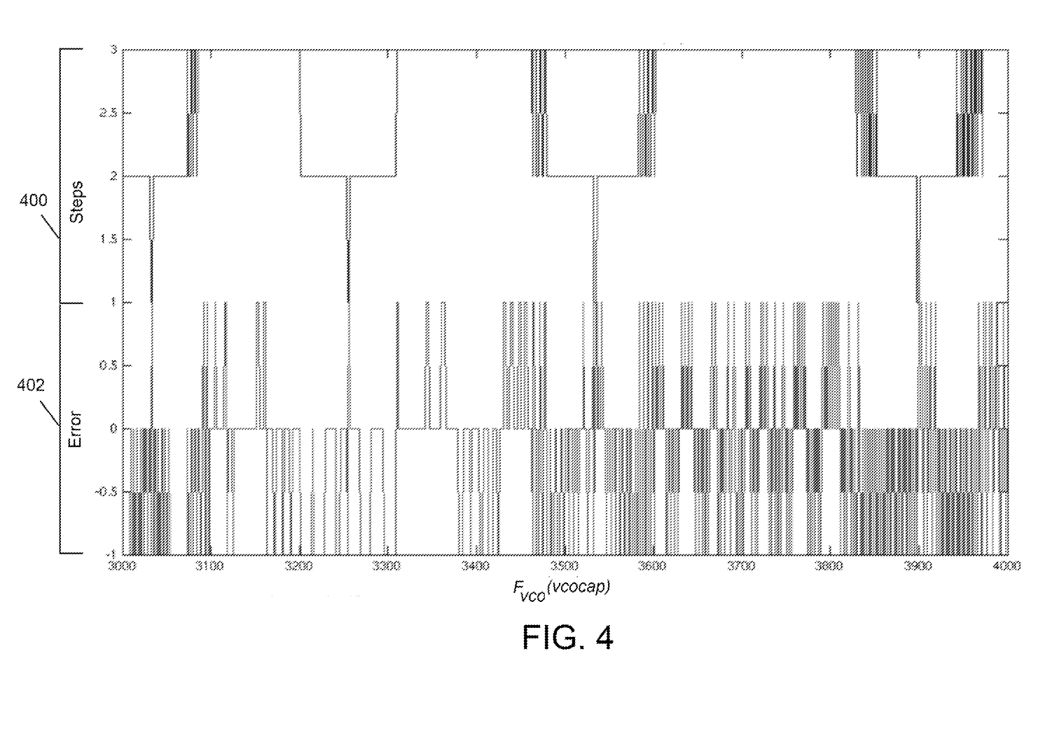

A simulation similar to that of FIG. 3 in which programming module 122 is configured to employ four frequency bins is depicted in FIG. 4. Again, the target frequency is swept from 3000 to 4000 along the x-axis, and the number of iterations 400 required for convergence, as well as the residual error 402 after convergence, are shown on the y-axis. This simulation indicates that programming module 122 may converge at an appropriate programming word in three steps or less when employing the non-successive iterative numerical technique of equation (6), with an error of +/−1 LSB. Further, the average number of steps required to achieve convergence is 2.56 steps. These directed determinations of the initial vcocap may be applied to any of the non-successive iterative numerical techniques of this disclosure, including those represented by equation (6) and by equation (7).

In yet another aspect of the disclosure, multi-bit capacitor arrays may be configured to divide the capacitor array into a coarse sub-array and a fine sub-array. By employing a unit capacitance for the fine sub-array less than the unit capacitance of the coarse sub-array, resolution of the capacitor array may be improved.

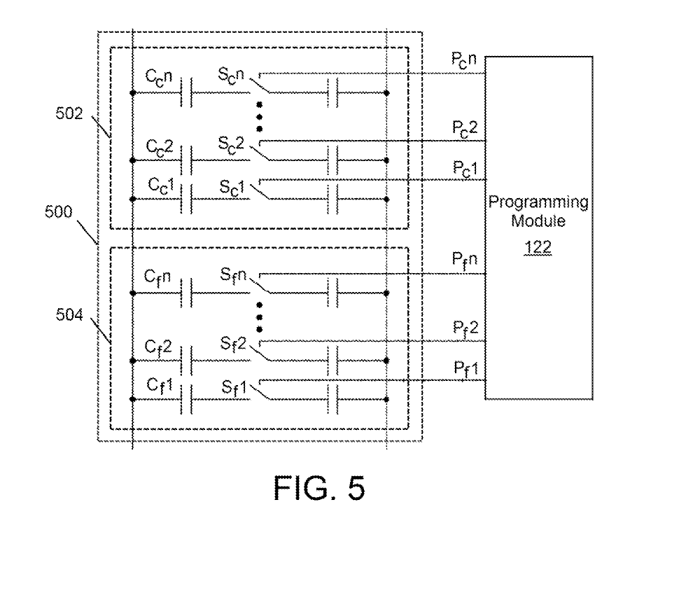

One embodiment of a suitable multi-bit capacitor array 500 is depicted in the detail view shown in FIG. 5. Multi-bit capacitor array 500 features a coarse sub-array 502 and a fine sub-array 504. In particular, coarse sub-array 502 includes a plurality of capacitor pairs C_{c}1-C_{c}n coupled in parallel and controlled by switches S_{f}1-S_{f}n. Each switch is controlled by programming module 122 by the corresponding programmable control lines P_{c}1-P_{c}n. Similarly, fine sub-array 504 includes a plurality of capacitor pairs C_{f}1-C_{f}n coupled in parallel and controlled by switches S_{f}l-S_{f}n. Each switch is controlled by programming module 122 by the corresponding programmable control lines P_{f}1-P_{f}n. In general, multi-bit capacitor array 500 may be substituted for multi-bit capacitor array 114 in LC resonant tank 110 of VCO 100.

Since fine sub-array 504 covers a narrower range, it may be configured to exhibit improved linearity with improved resolution. For example, the unit capacitance as represented by C_{c}1 may be relatively less than C1 of multi-bit capacitor array 114. Often, the total capacitance of fine sub-array 504 is larger than the unit capacitance of coarse sub-array 502, represented by C_{f}1, to help ensure coverage of the entire range of vcocap.

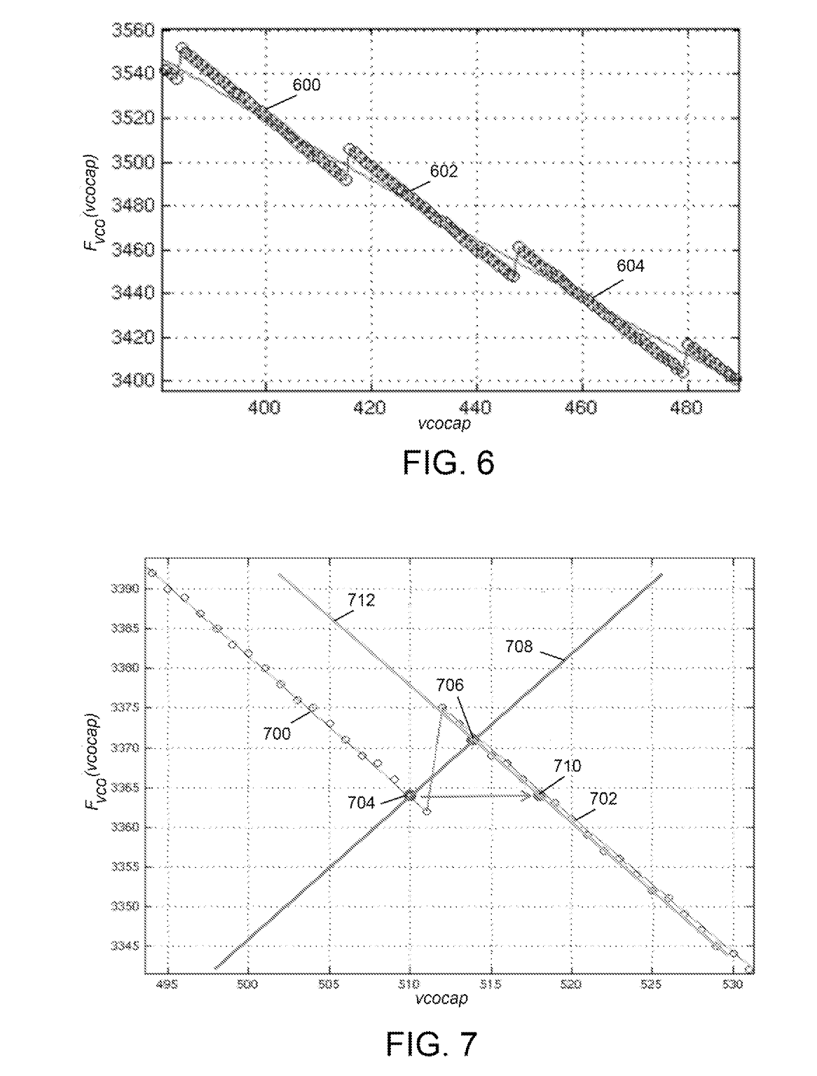

However, such a configuration results in a non-monotonic frequency curve as shown in FIG. 6. In this figure, a portion of the overall vcocap tuning range is depicted in detail. Each segment 600, 602 and 604 represents the total range of capacitance exhibited by fine sub-array 504, as achieved over three successive settings of coarse sub-array 502. The discontinuities in the tuning curve associated with transitions between coarse sub-array settings, such as between segments 600 and 602 or between segments 602 and 604, may complicate the determination of the next vcocap value in step 212 and result in non-convergence.

In one aspect, such discontinuities may be addressed by applying the non-successive iterative numerical techniques of this disclosure to coarse sub-array 502 and fine sub-array 504 as separate processes. Accordingly, for embodiments implementing the non-successive iterative numerical technique represented by equation (6), convergence may be achieved in √c+√f iterations, where c is the number of bits in coarse sub-array 502 and f is the number of bits in fine sub-array 504. Further, C_{LSB} corresponds to the LSB unit capacitance of coarse sub-array 502 when programming module 122 is determining the vcocap for coarse sub-array 502 and corresponds to the LSB unit capacitance of fine sub-array 504 when programming module 122 is determining the vcocap for fine sub-array 504. In addition, different thresholds may be applied in step 208 as the settings for coarse sub-array 502 may not be able to approach F_{target} as closely as the settings for fine sub-array 504.

Similarly, for embodiments implementing the non-successive iterative numerical technique represented by equation (7), convergence would be achieved in the same fashion as described above with order 1.618. Further, as described above fine sub-array 504 covers a narrow tuning range and may be configured to exhibit relatively greater linearity so that convergence may be achieved more quickly during this aspect of the programming word determination.

In another aspect, inaccurate determinations of convergence due to discontinuities in the tuning curve may be minimized by analyzing the slope exhibited by application of the non-successive iterative numerical techniques of the disclosure. The frequency versus capacitor relation may be expected to exhibit a negative slope, as increasing the vcocap may result in a decrease in resulting F_{vco}(vcocap). When programming module 122 detects a positive slope resulting from a transition from a first vcocap to a larger vcocap, it may be determined that a discontinuous portion of the frequency tuning curve may exist. For example, for embodiments implementing the non-successive iterative numerical technique represented by equation (7), the slope may be expressed as relationship shown in equation (8):

$$[ \frac{{vcocap}_{n } - {vcocap}_{n - 1}}{{F}_{vco} ( {vcocap}_{n} ) - {F}_{vco} ( {vcocap}_{n - 1} )} ] \qquad ( 8 )$$

An example of this aspect is depicted in reference to the frequency tuning curve of FIG. 7. A portion of the frequency tuning curve is shown including segments 700 and 702, which represent the total range of capacitance exhibited by fine sub-array 504, as achieved over two successive settings of coarse sub-array 502. As programming module 122 updates vcocap from vcocapₙ₋₁ represented by point 704 to vcocapₙ represented by point 706, a positive slope 708 may result. Accordingly, programming module 122 may be configured to determine that vcocap has transitioned to the adjacent coarse sub-array setting. To compensate, programming module 122 may then select a subsequent point 710 that exhibits a similar resulting F_{vco}(vcocap) to that associated with point 704 as indicated. Further, the validity of point 710 may be confirmed by checking that slope 712 calculated between points 708 and 710 is negative as expected.

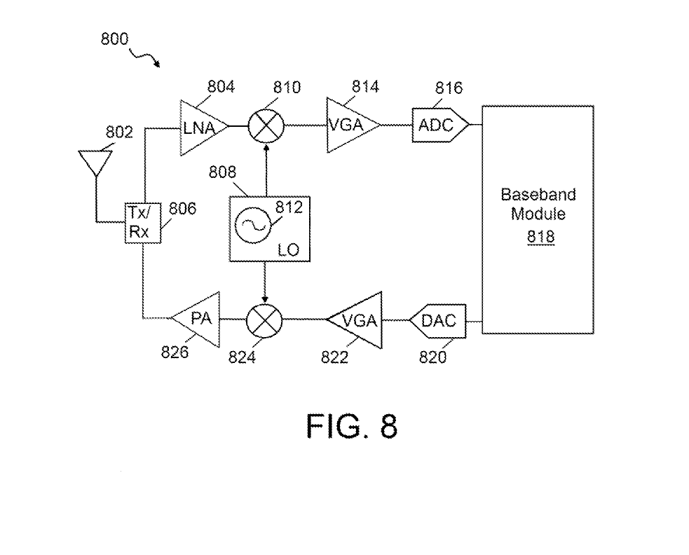

The techniques of this disclosure for tuning a multi-bit capacitor array of a VCO may be implemented in any suitable application. One exemplary embodiment is wireless communications device 800 as depicted in FIG. 8, which may be configured as a transceiver for use in a suitable wireless communications system, such as a wireless local area network (WLAN) system adhering to 802.11 protocols established by Institute of Electrical and Electronic Engineers (IEEE). In this simplified schematic depiction, wireless communications device 800 employs a direct conversion architecture, although any suitable design may be employed as desired, and may generally include a receive chain such that an information signal transmitted at RF may be received by antenna 802 and selectively coupled to LNA 804 by transmit/receive (Tx/Rx) switch 806. The amplified signal is downconverted to baseband frequency by combination with a suitable frequency signal output by local oscillator (LO) 808 at mixer 310. LO 808 may be implemented using a phase locked loop (PLL) architecture with VCO 812 having a multi-bit capacitor array tuned as described above. The downconverted signal may then be fed through variable gain amplifier (VGA) 814, digitized by analog to digital converter (ADC) 816 and delivered to baseband module 818 for further processing and demodulation to recover the transmitted information. Similarly, a digital information stream generated by baseband module 818 may be converted to a corresponding analog signal by digital to analog converter (DAC) 820 and then fed to VGA 822. The baseband frequency signal output by VGA 822 may then be upconverted at mixer 824 to RF for transmission by combining the baseband frequency signal with the frequency signal output by LO 808. The upconverted signal is amplified by power amplifier (PA) 826 and selectively coupled to antenna 802 by Tx/Rx switch 806.

The embodiments disclosed above are representative examples only. The principles of this disclosure can be extended to other applications as desired with appropriate modification.

What is claimed is:

1. A method for operating a frequency synthesizer with a voltage-controlled oscillator (VCO) having a first programmable array of capacitors comprising:
applying an initial setting to the first programmable array of capacitors;
measuring an initial frequency generated by the VCO at the initial setting;
determining a next setting for the first programmable array of capacitors using a non-successive iterative numerical technique;
applying the next setting to the first programmable array of capacitors;
measuring a frequency generated by the VCO at the next setting for the first programmable array of capacitors; and
repeating the determination of the next setting for the first programmable array of capacitors, the application of the next setting for the first programmable array of capacitors and the measurement of the generated frequency until the current frequency is within a first desired threshold of a target frequency.

2. The method of claim 1, wherein the non-successive iterative numerical technique comprises an equation relating frequency generated by the VCO and the capacitor setting of the first programmable array of capacitors.

3. The method of claim 2, wherein the equation is based on Newton's Method.

4. The method of claim 3, wherein the equation comprises
$${vcocap}_{n + 1} = {vcocap}_{n} + 2 \frac{{F}_{vco} ( {vcopcap}_{n} ) - {F}_{target}}{{F}_{vco} ( {vcocap}_{n} )} ( \frac{{C}_{FIXED}}{{C}_{LSB}} + {vcocap}_{n} ) ,$$
wherein C_{FIXED} is a fixed capacitance of an inductance-capacitance (LC) resonant tank of the VCO, C_{LSB} is an effective unit capacitance in the first programmable array of capacitors, vcocapₙ is a current setting of the first programmable array of capacitors, vcocapₙ₊₁ is the next setting, F_{vco}(vcocapₙ) is the current frequency generated by the VCO at the current setting and F_{target} is the target frequency.

5. The method of claim 1, wherein the non-successive iterative numerical technique comprises an equation depending upon a previously applied capacitor setting and measured frequency and a currently applied capacitor setting and measured frequency.

6. The method of claim 5, wherein the equation is based on a secant method.

7. The method of claim 6, wherein the equation comprises
$${vcocap}_{n + 1} = {vcocap}_{n} - [ {F}_{vco} ( {vcopcap}_{n} ) - {F}_{target} ] \frac{{vcocap}_{n} - {vcocap}_{n - 1}}{{F}_{vco} ( {vcocap}_{n} ) - {F}_{vco} ( {vcocap}_{n - 1} )} ,$$
wherein vcocapₙ₋₁ is a previous setting of the first programmable array of capacitors, vcocapₙ is a current setting of the first programmable array of capacitors, vcocapₙ₊₁ is the next setting, F_{vco}(vcocapₙ₋₁) is a frequency generated by the VCO at the previous setting, F_{vco}(vcocapₙ) is a frequency generated by the VCO at the current setting and F_{target} is the target frequency.

8. The method of claim 1, wherein applying the initial setting comprises estimating the initial setting based upon the target frequency.

9. The method of claim 1, wherein the first programmable array of capacitors comprises a coarse sub-array and wherein the VCO comprises a second programmable array of capacitors comprising a fine sub-array, further comprising:
applying an initial setting to the second programmable array of capacitors;
measuring the initial frequency generated by the VCO at the initial setting;
determining a next setting for the second programmable array of capacitors using the non-successive iterative numerical technique;
applying the next setting for the second programmable array of capacitors to the second programmable array of capacitors;
measuring the frequency generated by the VCO at the next setting for the second programmable array of capacitors; and
repeating the determination of the next setting for the second programmable array of capacitors, the application of the determined setting for the second programmable array of capacitors and the measurement of the generated frequency at the next setting for the second programmable array of capacitors until the generated frequency is within a second desired threshold of the target frequency.

10. The method of claim 1, wherein the first programmable array of capacitors comprises a coarse sub-array and a fine sub-array, further comprising:
determining a positive slope between a frequency generated at a previous setting of the first programmable array of capacitors and a frequency generated at a current setting of the first programmable array of capacitors; and
adjusting the next setting of the first programmable array of capacitors by selecting a setting that generates a frequency corresponding to the frequency generated at the previous setting.

11. A frequency synthesizer comprising:
a voltage-controlled oscillator (VCO) having a first programmable array of capacitors; and
a programming module,
wherein the programming module is configured to:
apply an initial setting to the first programmable array of capacitors;
measure an initial frequency generated by the VCO at the initial setting;
determine a next setting for the first programmable array of capacitors using a non-successive iterative numerical technique;
apply the next setting to the first programmable array of capacitors;
measure a current frequency generated by the VCO at the next setting; and
repeat the determination of the next setting for the first programmable array of capacitors, the application of the next setting for the first programmable array of capacitors and the measurement of the generated frequency until the current frequency is within a first desired threshold of a target frequency.

12. The frequency synthesizer of claim 11, wherein the non-successive iterative numerical technique comprises an equation relating frequency generated by the VCO and the capacitor setting of the first programmable array of capacitors.

13. The frequency synthesizer of claim 12, wherein the equation is based on Newton's Frequency synthesizer.

14. The frequency synthesizer of claim 13, wherein the equation comprises
$${vcocap}_{n + 1} = {vcocap}_{n} + 2 \frac{{F}_{vco} ( {vcopcap}_{n} ) - {F}_{target}}{{F}_{vco} ( {vcocap}_{n} )} ( \frac{{C}_{FIXED}}{{C}_{LSB}} + {vcocap}_{n} ) ,$$
wherein C_{FIXED} is a fixed capacitance of an inductance-capacitance (LC) resonant tank of the VCO, C_{LSB} is an effective unit capacitance in the first programmable array of capacitors, vcocapₙ is a current setting of the first programmable array of capacitors, vcocapₙ₊₁ is the next setting, F_{vco}(vcocapₙ) is the current frequency generated by the VCO at the current setting and F_{target} is the target frequency.

15. The frequency synthesizer of claim 11, wherein the non-successive iterative numerical technique comprises an equation depending upon a previously applied capacitor setting and measured frequency and a currently applied capacitor setting and measured frequency.

16. The frequency synthesizer of claim 15, wherein the equation is based on a secant method.

17. The frequency synthesizer of claim 16, wherein the equation comprises
$${vcocap}_{n + 1} = {vcocap}_{n} - [ {F}_{vco} ( {vcopcap}_{n} ) - {F}_{target} ] \frac{{vcocap}_{n} - {vcocap}_{n - 1}}{{F}_{vco} ( {vcocap}_{n} ) - {F}_{vco} ( {vcocap}_{n - 1} )} ,$$
wherein vcocapₙ₋₁ is a previous setting of the first programmable array of capacitors, vcocapₙ is a current setting of the first programmable array of capacitors, vcocapₙ₊₁ is the next setting, F_{vco}(vcocapₙ₋₁) is a frequency generated by the VCO at the previous setting, F_{vco}(vcocapₙ) is a frequency generated by the VCO at the current setting and F_{target} is the target frequency.

18. The frequency synthesizer of claim 11, wherein the programming module applies the initial setting by estimating the initial setting based upon the target frequency.

19. The frequency synthesizer of claim 11, wherein the first programmable array of capacitors comprises a coarse sub-array, wherein the VCO comprises a second programmable array of capacitors comprising a fine sub-array, and wherein the programming module is further configured to:
apply an initial setting to the second programmable array of capacitors;
measure the initial frequency generated by the VCO at the initial setting;
determine a next setting for the second programmable array of capacitors using the non-successive iterative numerical technique;
apply the next setting for the second programmable array of capacitors to the second programmable array of capacitors;
measure the frequency generated by the VCO at the next setting for the second programmable array of capacitors; and
repeat the determination of the next setting for the second programmable array of capacitors, the application of the determined setting for the second programmable array of capacitors and the measurement of the generated frequency at the next setting for the second programmable array of capacitors until the generated frequency is within a second desired threshold of the target frequency.

20. The frequency synthesizer of claim 11, wherein the first programmable array of capacitors comprises a coarse sub-array and a fine sub-array and wherein the programming module is further configured to:
determine a positive slope between a frequency generated at a previous setting of the first programmable array of capacitors and a frequency generated at a current setting of the first programmable array of capacitors; and
adjust the next setting of the first programmable array of capacitors by selecting a setting that generates a frequency corresponding to the frequency generated at the previous setting.

21. A wireless communications device comprising a voltage controlled oscillator (VCO) having a first programmable array of capacitors and a programming module, wherein the programming module is configured to:
apply an initial setting to the first programmable array of capacitors;
measure an initial frequency generated by the VCO at the initial setting;
determine a next setting for the first programmable array of capacitors using a non-successive iterative numerical technique;
apply the next setting to the first programmable array of capacitors;
measure a current frequency generated by the VCO at the next setting; and
repeat the determination of the next setting for the first programmable array of capacitors, the application of the next setting for the first programmable array of capacitors and the measurement of the generated frequency until the current frequency is within a first desired threshold of a target frequency.

22. The wireless communications device of claim 21, wherein the non-successive iterative numerical technique comprises an equation relating frequency generated by the VCO and the capacitor setting of the first programmable array of capacitors.

23. The wireless communications device of claim 22, wherein the equation is based on Newton's Wireless communications device.

24. The wireless communications device of claim 23, wherein the equation comprises
$${vcocap}_{n + 1} = {vcocap}_{n} + 2 \frac{{F}_{vco} ( {vcocap}_{n} ) - {F}_{target}}{{F}_{vco} ( {vcocap}_{n} )} ( \frac{{C}_{FIXED}}{{C}_{LSB}} + {vcocap}_{n} ) ,$$
wherein C_{FIXED} is a fixed capacitance of an inductance-capacitance (LC) resonant tank of the VCO, C_{LSB} is an effective unit capacitance in the first programmable array of capacitors, vcocapₙ is a current setting of the first programmable array of capacitors, vcocapₙ₊₁ is the next setting, F_{vco}(vcocapₙ) is the current frequency generated by the VCO at the current setting and F_{target} is the target frequency.

25. The wireless communications device of claim 21, wherein the non-successive iterative numerical technique comprises an equation depending upon a previously applied capacitor setting and measured frequency and a currently applied capacitor setting and measured frequency.

26. The wireless communications device of claim 25, wherein the equation is based on a secant method.

27. The wireless communications device of claim 26, wherein the equation comprises
$${vcocap}_{n + 1} = {vcocap}_{n} - [ {F}_{vco} ( {vcopcap}_{n} ) - {F}_{target} ] \frac{{vcocap}_{n} - {vcocap}_{n - 1}}{{F}_{vco} ( {vcocap}_{n} ) - {F}_{vco} ( {vcocap}_{n - 1} )} ,$$
wherein vcocapₙ₋₁ is a previous setting of the first programmable array of capacitors, vcocapₙ is a current setting of the first programmable array of capacitors, vcocapₙ₊₁ is the next setting, F_{vco}(vcocapₙ₋₁) is a frequency generated by the VCO at the previous setting, F_{vco}(vcocapₙ) is a frequency generated by the VCO at the current setting and F_{target} is the target frequency.

28. The wireless communications device of claim 21, wherein the programming module applies the initial setting by estimating the initial setting based upon the target frequency.

29. The wireless communications device of claim 21, wherein the first programmable array of capacitors comprises a coarse sub-array, wherein the VCO comprises a second programmable array of capacitors comprising a fine sub-array, and wherein the programming module is further configured to:
apply an initial setting to the second programmable array of capacitors;
measure the initial frequency generated by the VCO at the initial setting;
determine a next setting for the second programmable array of capacitors using the non-successive iterative numerical technique;
apply the next setting for the second programmable array of capacitors to the second programmable array of capacitors;
measure the frequency generated by the VCO at the next setting for the second programmable array of capacitors; and
repeat the determination of the next setting for the second programmable array of capacitors, the application of the determined setting for the second programmable array of capacitors and the measurement of the generated frequency at the next setting for the second programmable array of capacitors until the generated frequency is within a second desired threshold of the target frequency.

30. The wireless communications device of claim 21, wherein the first programmable array of capacitors comprises a coarse sub-array and a fine sub-array and wherein the programming module is further configured to:
determine a positive slope between a frequency generated at a previous setting of the first programmable array of capacitors and a frequency generated at a current setting of the first programmable array of capacitors; and
adjust the next setting of the first programmable array of capacitors by selecting a setting that generates a frequency corresponding to the frequency generated at the previous setting.
